(19) United States
(12) Patent Application Publication
(10) Pub. No.: US 2024/0317576 A1
(43) Pub. Date: Sep. 26, 2024

(54) OPTICAL REFLECTIVE DEVICE

(71) Applicant: Panasonic Intellectual Property Management Co., Ltd., Osaka (JP)

(72) Inventors: Kensuke MIHARA, Osaka (JP); Ryouichi TAKAYAMA, Osaka (JP)

(21) Appl. No.: 18/734,302

(22) Filed: Jun. 5, 2024

Related U.S. Application Data
(63) Continuation of application No. PCT/JP2022/035782, filed on Sep. 26, 2022.

(30) Foreign Application Priority Data
Dec. 8, 2021 (JP) 2021-199287

(51) Int. Cl. B81B 3/00; G02B 26/10

(52) U.S. Cl. CPC B81B 3/0072; G02B 26/105; H10N 30/704; B81B 2201/042; B81B 2203/0154; B81B 2203/058

(57) ABSTRACT

An optical reflective device includes: a movable part configured to be rotated about a rotation axis; a reflection surface located on the movable part; a frame part connected to the movable part at two positions symmetrical about the rotation axis; torsion part extending along the rotation axis; a connection part connecting one end of the torsion part to the frame part; a drive part connected to another end of the torsion part and configured to rotate the torsion part about the rotation axis; and a fixation part supporting the drive part, the connection part has higher rigidity than the torsion part, at least one pair of joint surfaces are formed at a boundary between the torsion part and the connection part, and the one pair of joint surfaces are symmetrical about the rotation axis and each have an acute angle on the torsion part side with the rotation axis.

### CROSS REFERENCE TO RELATED APPLICATION

This application is a continuation of International Application No. PCT/JP2022/035782 filed on Sep. 26, 2022, entitled “OPTICAL REFLECTIVE DEVICE”, which claims priority under 35 U.S.C. Section 119 of Japanese Patent Application No. 2021-199287 filed on Dec. 8, 2021, entitled “OPTICAL REFLECTIVE DEVICE”. The disclosures of the above applications are incorporated herein by reference.

### BACKGROUND OF THE INVENTION

### Field of the Invention

The present invention relates to an optical reflective device that rotates a reflection surface about a rotation axis.

### Description of Related Art

In recent years, by using micro electro mechanical system (MEMS) technology, optical reflective devices that rotate a reflection surface have been developed. In this type of optical reflective device, scanning can be performed at a predetermined deflection angle with a beam incident on the reflection surface. Such an optical reflective device is installed in image display apparatuses such as head-up displays and head-mounted displays. In addition, this type of optical reflective device can also be used in laser radars that use laser light to detect objects, etc.

In the configuration in which scanning is performed with light as the reflection surface rotates as described above, the reflection surface can be bent by an inertial force generated when the reflection surface repeatedly rotates. If the reflection surface is deformed into a concave or convex surface due to this bending, the beam spreads on a scanning line. Therefore, it is preferable to suppress the bending of the reflection surface as much as possible during rotation.

International Publication No. WO2013/046612 describes an optical reflective device of a type in which a mirror is rotated by a so-called tuning fork-type vibrator. In this optical reflective device, a frame is connected to an end portion of a drive beam extending along a rotation axis, and the mirror is also connected to the frame. The rigidity of the frame is made higher than that of the mirror. A piezoelectric actuator is placed on each of a pair of arm portions placed with the drive beam located therebetween. When the piezoelectric actuators are driven, the pair of arm portions vibrate and the drive beam rotates about the rotation axis. Accordingly, the frame and the mirror are repeatedly rotated.

In this configuration, since the frame is interposed between the mirror and the drive beam, the bending of the mirror during rotation is suppressed. Accordingly, the spread of a beam due to the bending of the mirror can be suppressed, so that the accuracy of scanning with the beam can be increased.

As described above, according to International Publication No. WO2013/046612, the bending of the mirror during rotation of the mirror can be suppressed by the action of the frame. However, when the optical reflective device having the above configuration is used, for example, in a laser scanning type image display apparatus, the mirror is required to be driven at a high frequency and a high deflection angle. In this case, a larger inertial force is generated in the mirror, so that a configuration for further suppressing the bending of the mirror is required.

### SUMMARY OF THE INVENTION

An optical reflective device according to a main aspect of the present invention includes: a movable part configured to be rotated about a rotation axis; a reflection surface located on the movable part; a frame part placed on an outer side of the movable part with a predetermined gap in a plan view and connected to the movable part at two positions symmetrical about the rotation axis; a beam-like torsion part extending along the rotation axis; a connection part connecting one end of the torsion part to the frame part; a drive part connected to another end of the torsion part and configured to rotate the torsion part about the rotation axis; and a fixation part supporting the drive part. The connection part has higher rigidity than the torsion part. At least one pair of joint surfaces are formed at a boundary between the torsion part and the connection part. The one pair of joint surfaces are symmetrical about the rotation axis and each have an acute angle on the torsion part side with the rotation axis.

In the optical reflective device according to this aspect, since the at least one pair of joint surfaces are symmetrical about the rotation axis and each have an acute angle on the torsion part side with the rotation axis, the stress generated during rotation of the movable part is more likely to spread to be dispersed to the pair of joint surfaces. Accordingly, the bending of the frame part during rotation of the movable part becomes gradual, so that the bending of the movable part connected to the frame part is suppressed. Therefore, even when the movable part is driven at a high frequency and a high deflection angle, the bending of the movable part and the reflection surface can be effectively suppressed.

The effects and the significance of the present invention will be further clarified by the description of the embodiment below. However, the embodiment below is merely an example for implementing the present invention. The present invention is not limited to the description of the embodiment below in any way.

### BRIEF DESCRIPTION OF THE DRAWINGS

FIG. 1 is a perspective view showing a configuration of an optical reflective device according to an embodiment as viewed from the upper side;

FIG. 2 is a perspective view showing the configuration of the optical reflective device according to the embodiment as viewed from the lower side;

FIG. 3 is a plan view showing the configuration of the optical reflective device according to the embodiment as viewed from below;

FIG. 4A and FIG. 4B are perspective views of the vicinity of a movable part according to the embodiment as viewed from the upper side and the lower side, respectively;

FIG. 4C and FIG. 4D are plan views of the vicinity of the movable part according to the embodiment as viewed from the upper side and the lower side, respectively;

FIG. 5 is an A1-A1 cross-sectional view of FIG. 4A according to the embodiment;

FIG. 6 is a perspective view showing the structures of connection parts according to the embodiment;

FIG. 7A and FIG. 7B are perspective views of the vicinity of a movable part according to a comparative example as viewed from the upper side and the lower side, respectively;

FIG. 7C and FIG. 7D are plan views of the vicinity of the movable part according to the comparative example as viewed from the upper side and the lower side, respectively;

FIG. 8A is a graph showing verification results according to the comparative example;

FIG. 8B is a graph showing verification results according to the embodiment;

FIG. 9A shows a simulation result of a stress distribution in an oxide film in a configuration of the comparative example;

FIG. 9B shows a simulation result of a stress distribution in an oxide film in the configuration of the embodiment;

FIG. 10A is a plan view schematically showing propagation of stress according to the comparative example;

FIG. 10B is a plan view schematically showing propagation of stress according to the embodiment;

FIG. 11A is a plan view of the vicinity of a movable part according to Modification 1 as viewed from the lower side;

FIG. 11B is a plan view of the vicinity of a movable part according to Modification 2 as viewed from the lower side;

FIG. 12A is a plan view of the vicinity of a movable part according to Modification 3 as viewed from the lower side;

FIG. 12B is a plan view of the vicinity of a movable part according to Modification 4 as viewed from the lower side; and

FIG. 13 is a plan view of an optical reflective device according to Modification 5 as viewed from the lower side.

It should be noted that the drawings are solely for description and do not limit the scope of the present invention by any degree.

### DETAILED DESCRIPTION

Hereinafter, an embodiment of the present invention will be described with reference to the drawings. For convenience, in each drawing, X, Y, and Z axes that are orthogonal to each other are additionally shown. The Y-axis direction is a direction parallel to a rotation axis of an optical reflective device, and the Z-axis direction is the thickness direction of the optical reflective device.

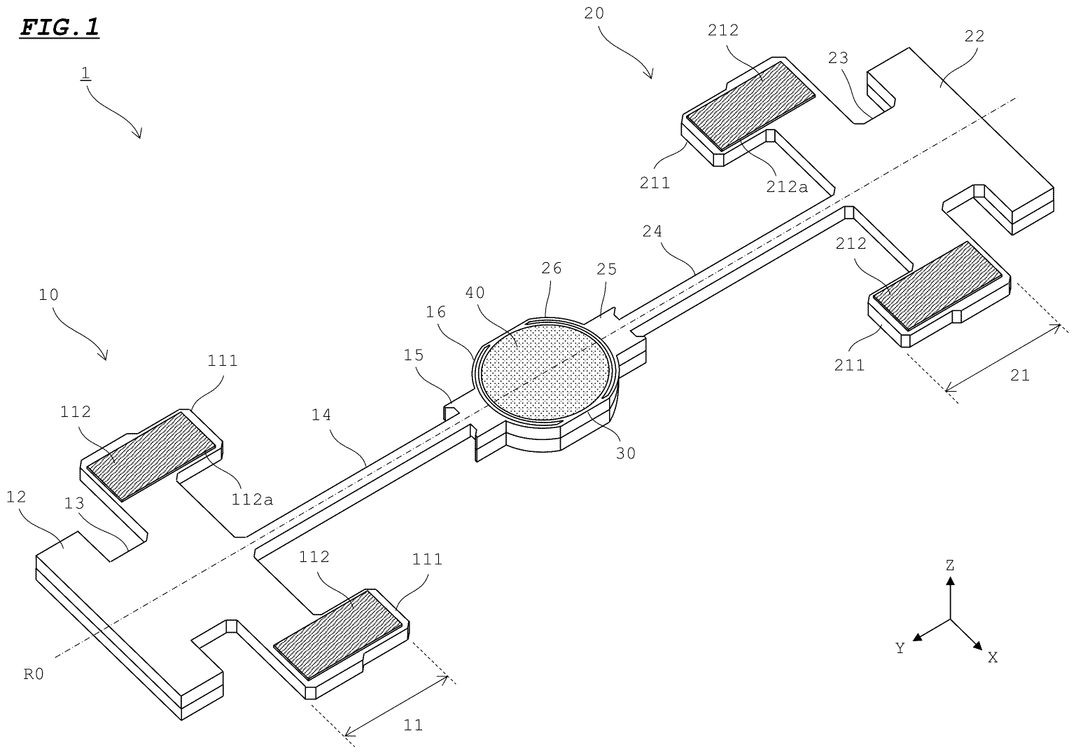

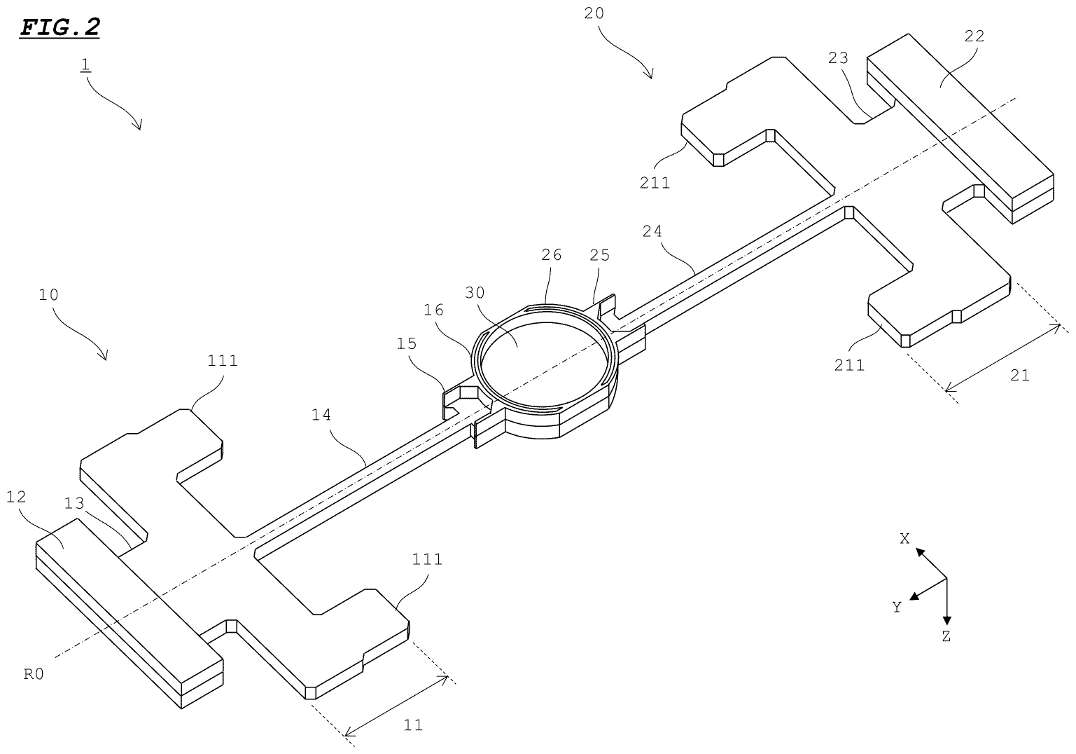

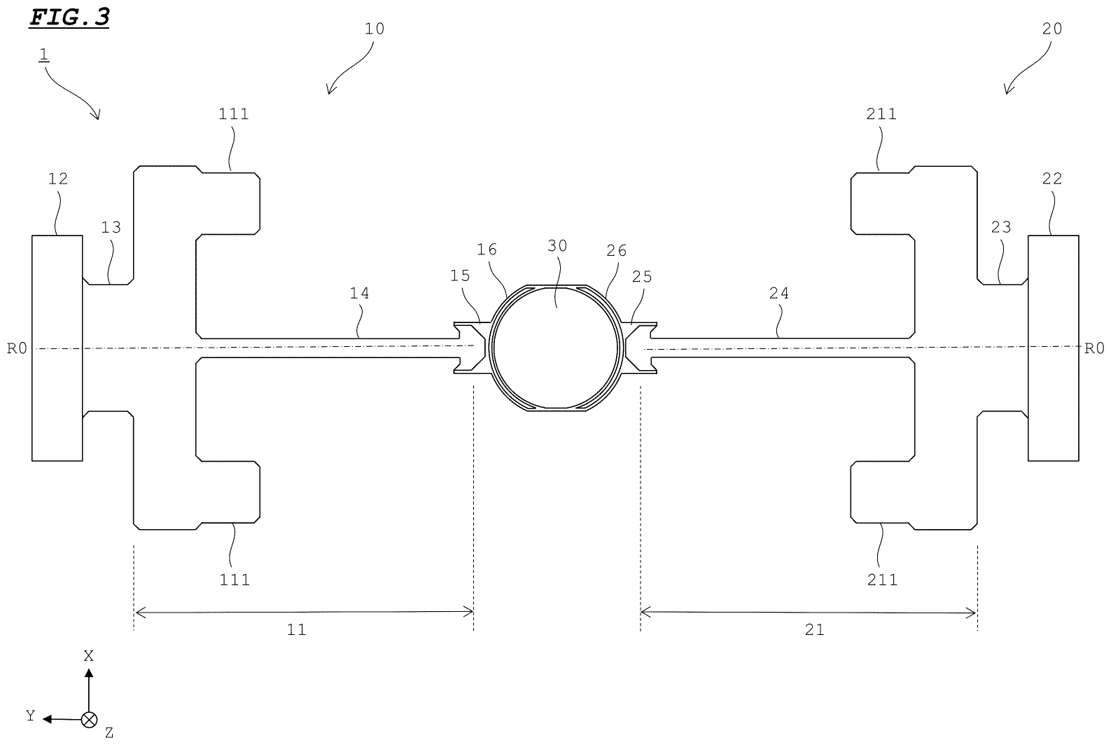

FIG. 1 and FIG. 2 are perspective views showing a configuration of an optical reflective device 1 as viewed from the upper side and the lower side, respectively, and FIG. 3 is a plan view showing the configuration of the optical reflective device 1. FIG. 3 shows a plan view of the optical reflective device 1 as viewed from the lower side (Z-axis negative side).

As shown in FIG. 1 to FIG. 3, the optical reflective device 1 includes a first drive unit 10, a second drive unit 20, and a movable part 30. In addition, a reflection surface 40 is located on the upper surface of the movable part 30. The optical reflective device 1 has a symmetrical shape in the X-axis direction and the Y-axis direction in a plan view. The movable part 30 and the reflection surface 40 are circular in a plan view.

The reflection surface 40 is formed, for example, by stacking a dielectric multilayer film on the upper surface of the movable part 30. The movable part 30 and the reflection surface 40 may be formed from the same material. In this case, for example, the reflection surface 40 may be formed by performing mirror finish on the upper surface of the movable part 30.

The first drive unit 10 and the second drive unit 20 repeatedly rotate the movable part 30 about a rotation axis R0 in response to drive signals supplied thereto from drive circuits which are not shown. The reflection surface 40 reflects light incident thereon from above the movable part 30, in a direction corresponding to a deflection angle of the movable part 30. Accordingly, as the movable part 30 rotates, the light (e.g., laser light) incident on the reflection surface 40 is deflected and scanning is performed with this light.

The first drive unit 10 includes a drive part 11, a fixation part 12, a support part 13, a torsion part 14, a connection part 15, and a frame part 16. The movable part 30, the drive part 11, the fixation part 12, the support part 13, the torsion part 14, the connection part 15, and the frame part 16 are aligned along the rotation axis R0.

The second drive unit 20 includes a drive part 21, a fixation part 22, a support part 23, a torsion part 24, a connection part 25, and a frame part 26. The movable part 30, the drive part 21, the fixation part 22, the support part 23, the torsion part 24, the connection part 25, and the frame part 26 are aligned along the rotation axis R0.

The first drive unit 10 and the second drive unit 20 are placed in orientations opposite to each other with the movable part 30 located therebetween. The frame part 16 of the first drive unit 10 and the frame part 26 of the second drive unit 20 are connected to the movable part 30.

The drive part 11 is a tuning fork-type vibrator. The drive part 11 includes a pair of arm portions 111 extending in an L-shape from the rotation axis R0, and piezoelectric drivers 112 formed on the upper surfaces of the pair of arm portions 111, respectively. The piezoelectric drivers 112 are formed on the upper surfaces of straight portions, of the arm portions 111, extending in the Y-axis direction.

The drive part 21 is a tuning fork-type vibrator. The drive part 21 includes a pair of arm portions 211 extending in an L-shape from the rotation axis R0, and piezoelectric drivers 212 formed on the upper surfaces of the pair of arm portions 211, respectively. The piezoelectric drivers 212 are formed on the upper surfaces of straight portions, of the arm portions 211, extending in the Y-axis direction.

The piezoelectric drivers 112 and 212 each have a lamination structure in which electrode layers are respectively placed on the upper and lower sides of a piezoelectric thin film 112a or 212a having a predetermined thickness. The piezoelectric thin films 112a and 212a are made of, for example, a piezoelectric material having a high piezoelectric constant, such as lead zirconate titanate (PZT). The electrode layers are made of a material having low electrical resistance and high heat resistance, such as platinum (Pt). The piezoelectric drivers 112 and 212 are each placed on the upper surface of the arm portion 111 or 211 by forming a layer structure, which includes the piezoelectric thin film 112a or 212a and the electrode layers on the upper and lower sides thereof, on the upper surface of the arm portion 111 or 211 by a sputtering method or the like.

The drive part 11 is connected to the fixation part 12 via the support part 13. In addition, the drive part 21 is connected to the fixation part 22 via the support part 23.

The torsion parts 14 and 24 each have a beam-like shape extending along the rotation axis R0. The torsion parts 14 and 24 each have a quadrangular cross-section. Here, the cross-sections of the torsion parts 14 and 24 are squares. The cross-sections of the torsion parts 14 and 24 may each have another shape such as a rectangular shape or a circular shape.

The drive part 11 is connected to an end portion on the Y-axis positive side of the torsion part 14, and an end portion on the Y-axis negative side of the torsion part 14 is connected to the frame part 16 via the connection part 15. In addition, the drive part 21 is connected to an end portion on the Y-axis negative side of the torsion part 24, and an end portion on the Y-axis positive side of the torsion part 24 is connected to the frame part 26 via the connection part 25.

A substrate of the optical reflective device 1 has the same contour as the optical reflective device 1 in a plan view, and has a constant thickness. The reflection surface 40 and the piezoelectric drivers 112 and 212 are placed in corresponding regions of the upper surface of the substrate. In addition, a predetermined material is further stacked on the lower surfaces of portions, of the substrate, corresponding to the fixation parts 12 and 22, the connection part 15, and the frame part 16, thereby increasing the thicknesses of the fixation parts 12 and 22, the connection part 15, and the frame part 16. In addition, a predetermined material is also stacked on a region along the outer circumference of the lower surface of the movable part 30, thereby forming a rib along the outer circumference of the lower surface of the movable part 30. The material stacked on the substrate may be a material different from that of the substrate, or may be the same material as the substrate.

The substrate is, for example, integrally formed from silicon or the like. However, the material forming the substrate is not limited to silicon, and may be another material. The material forming the substrate is preferably a material having high mechanical strength and Young's modulus, such as metal, crystal, glass, and resin. As such a material, in addition to silicon, titanium, stainless steel, Elinvar, a brass alloy, etc., can be used. The same applies to the material stacked on the substrate. An oxide film is formed on the region of the substrate where the lamination structure is formed, and the material for increasing the above thicknesses is stacked on the oxide film.

In the configuration of FIG. 1, when the piezoelectric drivers 112 and 212 are driven in response to drive signals, the pair of arm portions 111 and the pair of arm portions 211 vibrate in the Z-axis direction, and the torsion parts 14 and 24 repeatedly rotate around the rotation axis R0. Accordingly, the movable part 30 repeatedly rotates together with the frame part 16, and the reflection surface 40 repeatedly rotates.

Next, the structures of the connection parts 15 and 25 and the frame parts 16 and 26 will be described in more detail.

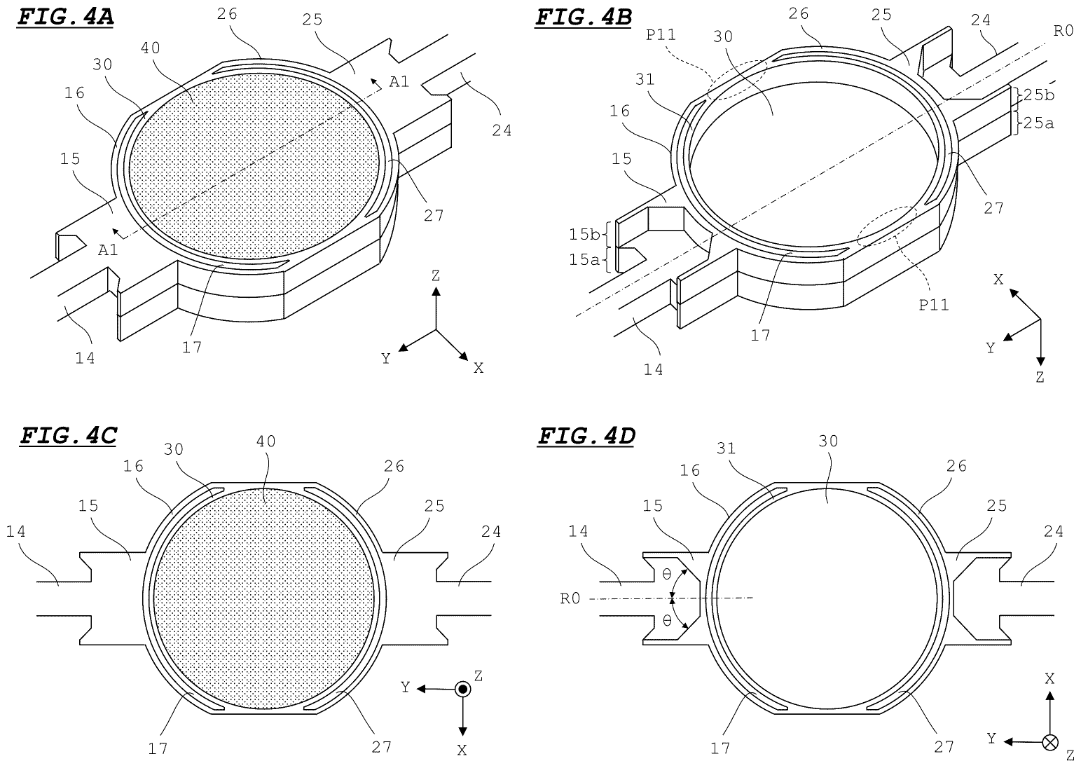

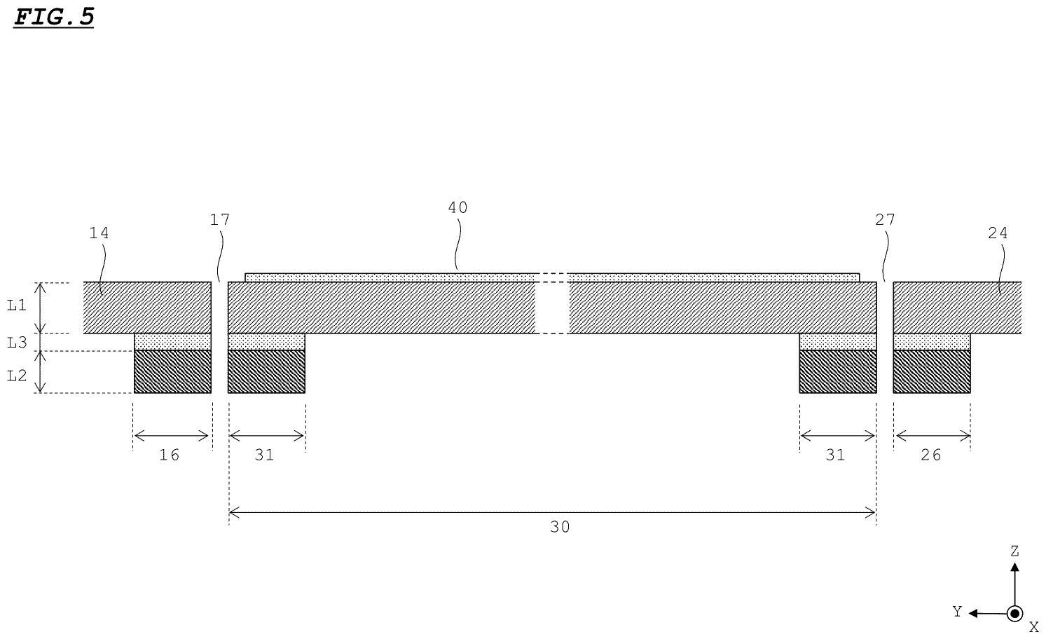

FIG. 4A and FIG. 4B are perspective views of the vicinity of the movable part 30 as viewed from the upper side and the lower side, respectively, and FIGS. 4C and 4D are plan views of the vicinity of the movable part 30 as viewed from the upper side and the lower side, respectively. FIG. 5 is an A1-A1 cross-sectional view of FIG. 4A.

As shown in FIG. 4B and FIG. 4D, a rib 31 is formed along the outer circumference of the movable part 30. The rib 31 is formed by further stacking the material on the lower surface of the substrate as described above. That is, as shown in FIG. 5, an oxide film L3 is formed on a region, corresponding to the rib 31, of the lower surface of a substrate layer L1, and a material layer L2 is formed on the lower surface of the oxide film L3. The rib 31 increases the rigidity of the movable part 30 and suppresses the bending of the movable part 30 during rotation.

As shown in FIG. 4A to FIG. 4D, a pair of the frame parts 16 and 26 are placed on the outer side of the movable part 30 in a plan view. The frame parts 16 and 26 are placed on the outer side of the movable part 30 with predetermined gaps 17 and 27, and are each connected to the movable part 30 at two positions P11 symmetrical about the rotation axis R0. The gaps 17 and 27 extend in an arc shape along a circle concentric with the center of the movable part 30. The widths of the gaps 17 and 27 are constant except at both ends thereof. The frame parts 16 and 26 are formed in an arc shape along the gaps 17 and 27.

The frame parts 16 and 26 each have an increased thickness and therefore increased rigidity as compared to the region of the movable part 30 other than the rib 31. That is, as shown in FIG. 5, the oxide film L3 is formed on regions, corresponding to the frame parts 16 and 26, of the lower surface of the substrate layer L1, and the material layer L2 is formed on the lower surface of the oxide film L3. Accordingly, the rigidity of the frame parts 16 and 26 is made higher than that of the movable part 30 other than the rib 31. As shown in FIG. 5, the gaps 17 and 27 penetrate in the up-down direction.

As shown in FIG. 4B, the thicknesses of the connection parts 15 and 25 are larger than the thicknesses of the torsion parts 14 and 24. Accordingly, the rigidity of the connection parts 15 and 25 is made higher than that of the torsion parts 14 and 24.

The connection parts 15 and 25 have thickness ranges 15a and 25a (hereinafter referred to as “joint ranges 15a and 25a”) connected to the torsion parts 14 and 24 and thickness ranges 15b and 25b (hereinafter referred to as non-joint ranges 15b and 25b) not connected to the torsion parts 14 and 24. The joint ranges 15a and 25a are ranges corresponding to the substrate layer L1 in FIG. 5, and the non-joint ranges 15b and 25b are ranges corresponding to the material layer L2 and the oxide film L3 in FIG. 5. The thicknesses of the connection parts 15 and 25 are increased from the torsion parts 14 and 24 by those of the non-joint ranges 15b and 25b, thereby making the rigidity of the connection parts 15 and 25 higher than that of the torsion parts 14 and 24.

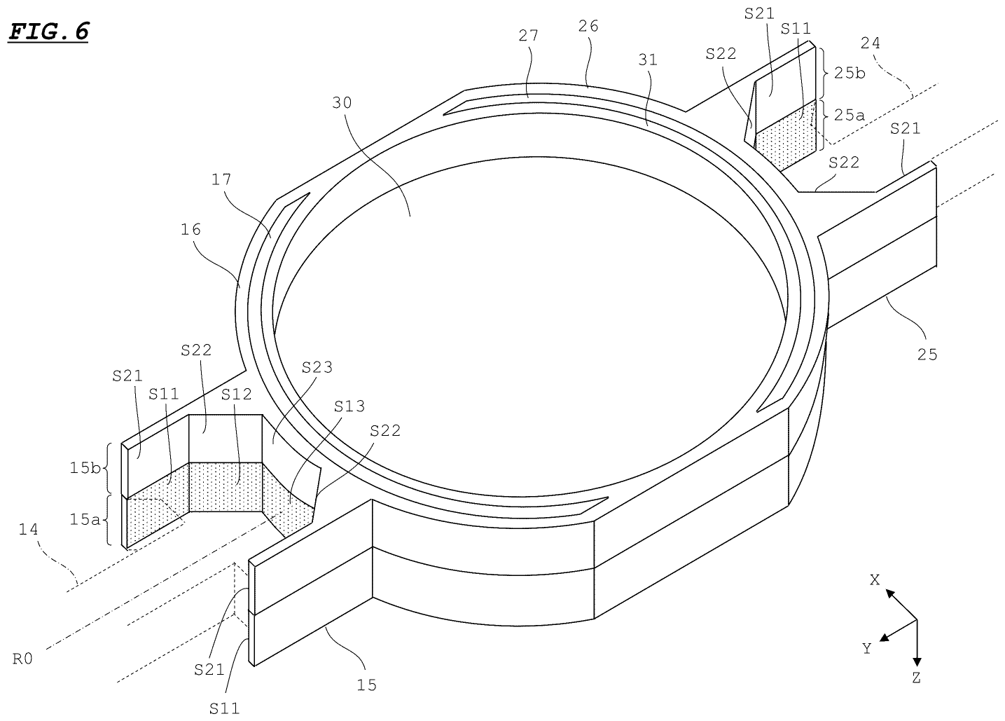

FIG. 6 is a perspective view showing the structures of the connection parts 15 and 25. For convenience, in FIG. 6, a state where the torsion parts 14 and 24 are seen through is shown, and the torsion parts 14 and 24 are shown by broken lines.

In the joint range 15a, a joint surface between the torsion part 14 and the connection part 15 is formed at the boundary between the torsion part 14 and the connection part 15. Here, a pair of joint surfaces S11, a pair of joint surfaces S12, and one joint surface S13 are formed at the boundary between the torsion part 14 and the connection part 15. In FIG. 6, the joint surface S12 on the X-axis negative side out of the pair of joint surfaces S12 is hidden by a portion on the X-axis negative side of the connection part 15 and thus not seen.

The pair of joint surfaces S12 are surfaces parallel to the Y-Z plane, and are parallel to the rotation axis R0 in a plan view. In addition, the pair of joint surfaces S12 are inclined in opposite directions by the same angle with respect to the rotation axis R0 in a plan view. Of the angles between each of the pair of joint surfaces S12 and the rotation axis R0, an angle θ on the torsion part 14 side (see FIG. 4D) is an acute angle. Here, the angle θ is set to about 45°. The joint surface S12 is a flat surface parallel to the Z axis. The joint surface S13 is substantially perpendicular to the rotation axis R0. The shape of the joint surface S13 in a plan view is an arc having the same diameter as the outer circumference of the frame part 16.

In the non-joint range 15b, a pair of wall surfaces S21 connected to the pair of joint surfaces S11 in the Z-axis negative direction and a pair of wall surfaces S22 connected to the pair of joint surfaces S12 in the Z-axis negative direction are formed. Furthermore, a wall surface S23 connected to the joint surface S13 in the Z-axis negative direction is formed in the non-joint range 15b. The joint surface S11 and the wall surface S21 connected thereto are parallel to and flush with each other. The joint surface S12 and the wall surface S22 connected thereto are parallel to and flush with each other. The joint surface S13 and the wall surface S23 connected thereto are parallel to and flush with each other.

By forming the pair of wall surfaces S21, the pair of wall surfaces S22, and the wall surface S23 in the non-joint range 15b, the joint surfaces S11, S12, and S13 extending from these wall surfaces in the Z-axis positive direction are formed in the joint range 15a. That is, the shapes of the pair of joint surfaces S11, the pair of joint surfaces S12, and the joint surface S13 in a plan view are defined by the shapes of the pair of wall surfaces S21, the pair of wall surfaces S22, and the wall surface S23 in a plan view. The adjacent wall surfaces S21 and S22 and the adjacent wall surfaces S22 and S23 are in contact with each other at the borders thereof, and thus the adjacent joint surfaces S11 and S12 and the adjacent joint surfaces S12 and S13 are also in contact with each other at the borders thereof.

As in the joint range 15a of the connection part 15, a pair of joint surfaces S11, a pair of joint surfaces S12, and a joint surface S13 are also formed in the joint range 25a of the connection part 25 on the Y-axis negative side. In addition, as in the non-joint range 15b of the connection part 15, a pair of wall surfaces S21, a pair of wall surfaces S22, and a wall surface S23 are also formed in the non-joint range 25b of the connection part 25 on the Y-axis negative side. The pair of joint surfaces S11 on the connection part 25 side are also parallel to the rotation axis R0. In addition, an angle θ on the torsion part 24 side between each of the pair of joint surfaces S12 on the connection part 25 side and the rotation axis R0 is also an acute angle (here, about) 45°.

In the present embodiment, by forming the pair of joint surfaces S11 and the pair of joint surfaces S12 in each of the connection parts 15 and 25 as described above, stress applied from the torsion parts 14 and 24 to the connection parts 15 and 25 during rotational movement of the movable part 30 is reduced. Accordingly, the bending of the frame parts 16 and 26 is suppressed, and as a result, the bending of the movable part 30 and the reflection surface 40 is suppressed. This effect will be described below in comparison to a comparative example.

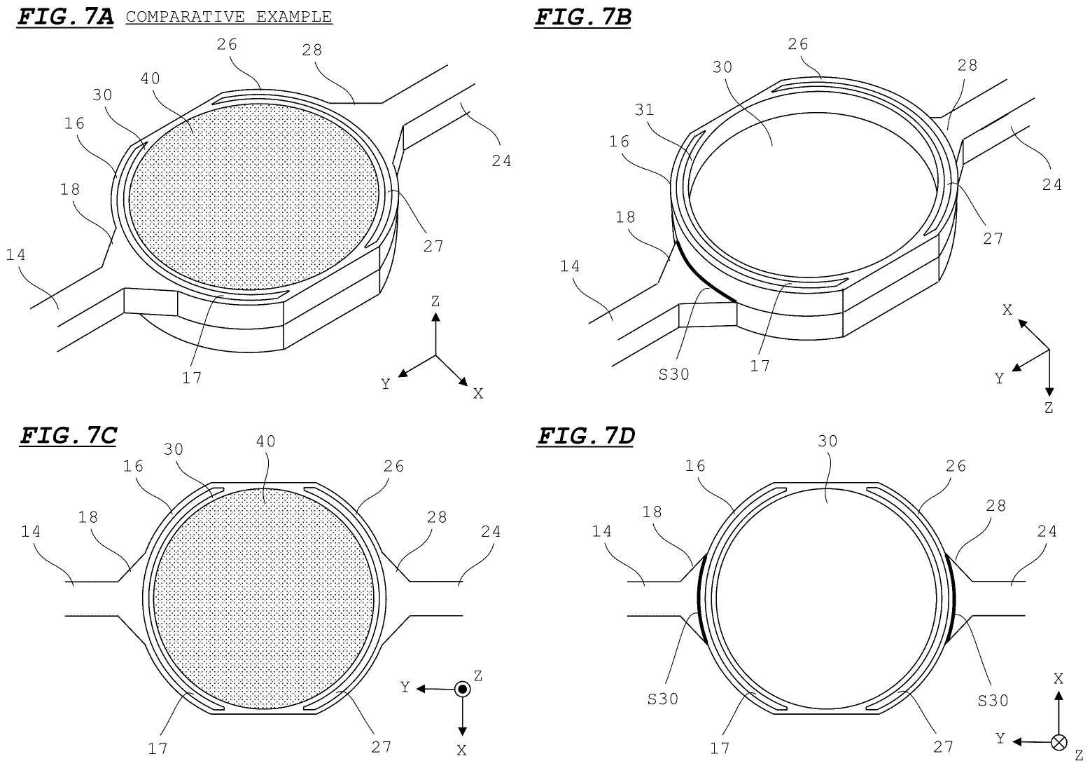

FIG. 7A and FIG. 7B are perspective views of the vicinity of a movable part 30 of an optical reflective device 1 according to the comparative example as viewed from the upper side and the lower side, respectively, and FIG. 7C and FIG. 7D are plan views of the vicinity of the movable part 30 of the optical reflective device 1 according to the comparative example as viewed from the upper side and the lower side, respectively.

In the comparative example, as shown in FIG. 7A to FIG. 7D, only the configurations of connection parts 18 and 28 are different from those of the connection parts 15 and 25 of the above embodiment. The configuration of the optical reflective device 1 other than the connection parts 18 and 28 is the same as that of the embodiment shown in FIG. 1 to FIG. 6. That is, in the comparative example, the thicknesses of the connection parts 18 and 28 are the same as the thicknesses of the torsion parts 14 and 24. The connection parts 18 and 28 are composed of only the substrate layer L1 in FIG. 5.

The widths of the connection parts 18 and 28 gradually widen toward the frame parts 16 and 26. At joint surfaces S30, the connection parts 18 and 28 are connected to the frame parts 16 and 26. The shape of each joint surface S30 in a plan view is an arc. In FIG. 7B and FIG. 7D, the end edges on the Z-axis negative side of the joint surfaces S30 are shown. The joint surfaces S30 extend from the arc-shaped end edges thereof to the lower surfaces on the Z-axis negative side of the connection parts 18 and 28 in the Z-axis positive direction of the frame parts 16 and 26.

The inventors obtained the bending of the frame parts 16 and 26 and the movable part 30 by simulation for the optical reflective device 1 according to the comparative example and the optical reflective device 1 according to the above embodiment.

In this simulation, the diameter of the movable part 30 (including the rib 31) was set to 1.0 mm, and the widths in the radial direction of the frame parts 16 and 26 and the widths in the radial direction of the gaps 17 and 27 were each set to 25 μm. In addition, the thickness of the substrate layer L1 shown in FIG. 5 was set to 150 μm, and the thickness of the material layer L2 was set to 140 μm. The thickness of the oxide film L3 was set to 1 μm. For the optical reflective devices 1 of the comparative example and the embodiment configured as described above, an optical scanning angle (total optical angle) of the reflection surface 40 (movable part 30) by repetitive rotation in which the reflection surface 40 was repeatedly rotated at 60 kHz was set to 65° in both the comparative example and the embodiment.

In the verification, the bending amount of each part (split element) in a state where the movable part 30 and the frame parts 16 and 26 were bent most when the movable part 30 was rotated according to the above conditions was obtained by a finite element method. The bending amount was obtained by the difference in the height direction between the position (reference position) of each of the movable part 30 and the frame parts 16 and 26 when the movable part 30 and the frame parts 16 and 26 were rotated without bending and the actual position (variable position) of each of the movable part 30 and the frame parts 16 and 26.

A positive sign is assigned to the difference when each part is displaced upward from a state where there is no bending in each part, and a negative sign is assigned to the difference when each part is displaced downward from a state where there is no bending in each part. A positive sign is assigned to the position of each part when this position is away from the rotation axis R0 in one direction parallel to the reflection surface 40 and perpendicular to the rotation axis R0, and a negative sign is assigned to the position of each part, on a reference plane, away from the rotation axis R0 in the other direction parallel to the reflection surface 40 and perpendicular to the rotation axis R0.

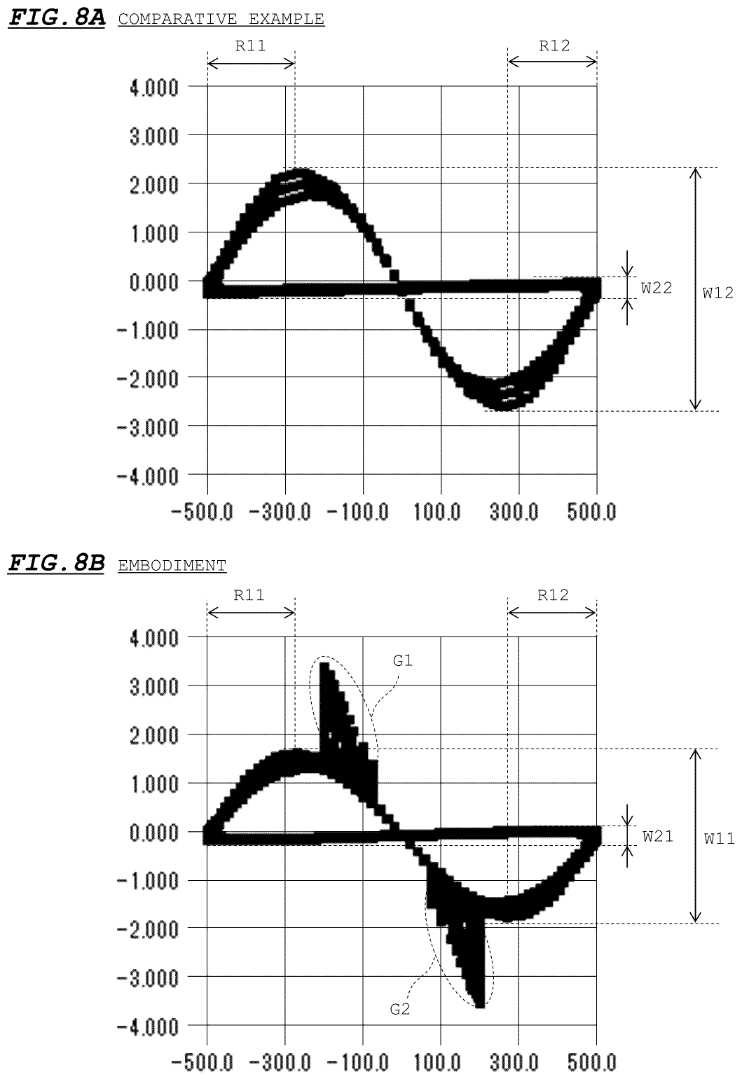

FIG. 8A is a graph showing verification results according to the comparative example, and FIG. 8B is a graph showing verification results according to the embodiment.

In FIG. 8A and FIG. 8B, the horizontal axis indicates the position of each part described above, and the vertical axis indicates the bending amount at each position. Here, the bending amount (displacement amount in the height direction) of each part when viewed parallel to the rotation axis R0 is plotted in the graphs. The units for the vertical axis and the horizontal axis are μm.

In FIG. 8A and FIG. 8B, data groups that vary sinusoidally indicate the bending amount at each position of the frame parts 16 and 26, and linear band-shaped data groups whose values on the vertical axis are around zero indicate the bending amount at each position of the movable part 30.

Referring to FIG. 8A and FIG. 8B, in the configuration of the embodiment, a variation range W11 of the bending amount of the frame parts 16 and 26 is reduced as compared to a variation range W12 of the bending amount of the frame parts 16 and 26 in the configuration of the comparative example. In addition, in the configuration of the embodiment, a variation range W21 of the bending amount of the movable part 30 is reduced as compared to a variation range W22 of the bending amount of the movable part 30 in the configuration of the comparative example. Specifically, in the configuration of the comparative example, the variation range W22 of the bending amount of the movable part 30 was 64 nm. In contrast, in the configuration of the embodiment, the variation range W21 of the bending amount of the movable part 30 was 53 nm and was reduced by about 20% as compared to the comparative example.

Thus, in the configuration of the embodiment, the bending of the movable part 30 during rotation of the movable part 30 is more effectively suppressed than in the comparative example, so that the deformation of the reflection surface 40 into a concave or convex surface during rotational movement is effectively suppressed. Therefore, the spread of a beam on a scanning line can be more reliably suppressed.

In the configuration of the embodiment, as shown in FIG. 8B, the bending of the frame parts 16 and 26 is further increased from a sinusoidal waveform in regions G1 and G2. However, the regions G1 and G2 are located close to the rotation axis R0, and thus are less likely to affect the bending of the movable part 30.

That is, as shown in FIG. 4B, the movable part 30 is connected to the frame parts 16 and 26 at the positions P11 in the vicinities of the most distant end portions on the X-axis positive side and the X-axis negative side. Therefore, as for the bending of the frame parts 16 and 26 during rotational movement, the bending in ranges close to these positions P11 greatly affects the bending of the movable part 30. The ranges close to these positions P11 correspond to ranges R11 and R12 in FIG. 8A and FIG. 8B. On the other hand, the regions G1 and G2 are on the inner side with respect to the ranges R11 and R12 and are not included in the ranges R11 and R12. Therefore, The bending of the frame parts 16 and 26 in the regions G1 and G2 is less likely to affect the bending of the movable part 30. As a result, in the configuration of the embodiment, even though large bending occurs in the regions G1 and G2, the bending of the movable part 30 is suppressed as compared to the comparative example.

Next, the inventors examined the mechanism by which the bending of the frame parts 16 and 26 is suppressed in the configuration of the embodiment. First, the inventors obtained, by simulation, a stress distribution generated in the oxide film L3 when the movable part 30 was repeatedly rotated under the above simulation conditions.

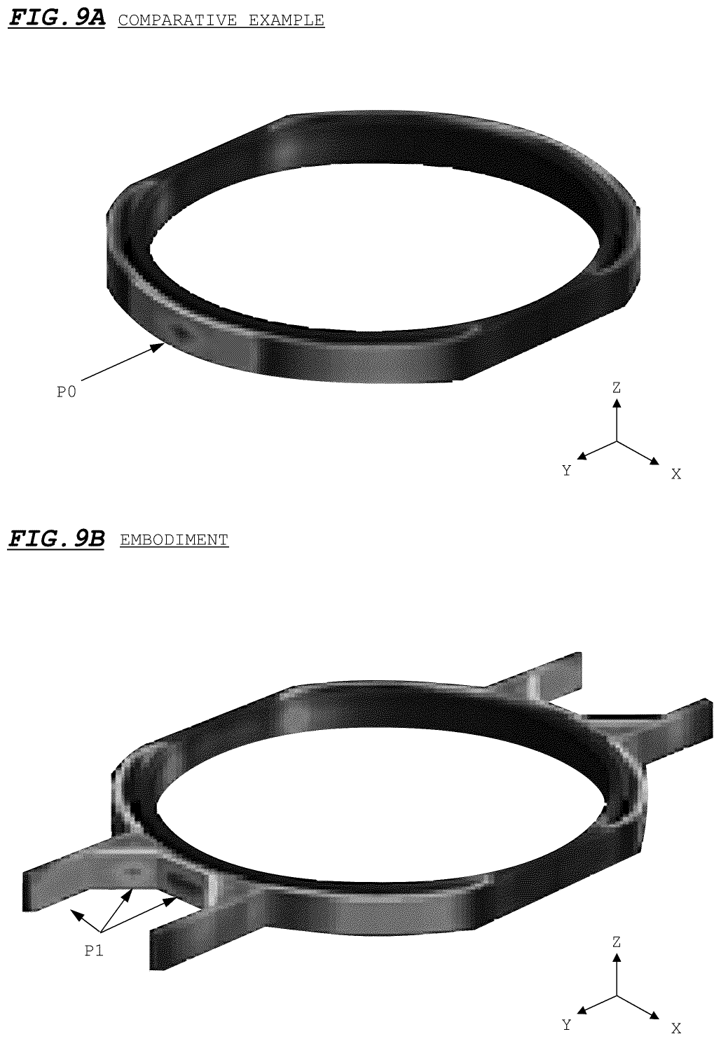

FIG. 9A shows the simulation result of the stress distribution in the oxide film L3 in the configuration of the comparative example, and FIG. 9B shows the simulation result of the stress distribution in the oxide film L3 in the configuration of the embodiment. For convenience, in FIG. 9A and FIG. 9B, a simulation result with a minimum value in blue and a maximum value in red is shown in grayscale.

FIG. 9A and FIG. 9B each show a stress distribution when the movable part 30 was rotated at a maximum deflection angle. FIG. 9A and FIG. 9B each show a stress distribution at an end portion on the Y-axis positive side, and a stress distribution at an end portion on the Y-axis negative side was also substantially the same as in FIG. 9A and FIG. 9B.

As shown in FIG. 9A, in the configuration of the comparative example, stress is concentrated at a position P0 corresponding to the vicinity of the center of the joint surface S30 (see FIG. 7B and FIG. 7D). In contrast, in the configuration of the embodiment, as shown in FIG. 9B, stress is dispersed to positions P1 corresponding to the pair of joint surfaces S11, the pair of joint surfaces S12, and the joint surface S13 (see FIG. 6). Such a stress distribution is considered to be generated by the deformation of the oxide film L3 due to the deformation of the substrate layer L1 adjacent to the oxide film L3 during rotational movement. Therefore, it is presumed that a stress distribution similar to that in FIG. 9A is also generated at the joint surface S30 in the configuration of the comparative example, and a stress distribution similar to that in FIG. 9B is also generated at the pair of joint surfaces S11, the pair of joint surfaces S12, and the joint surface S13 in the configuration of the embodiment.

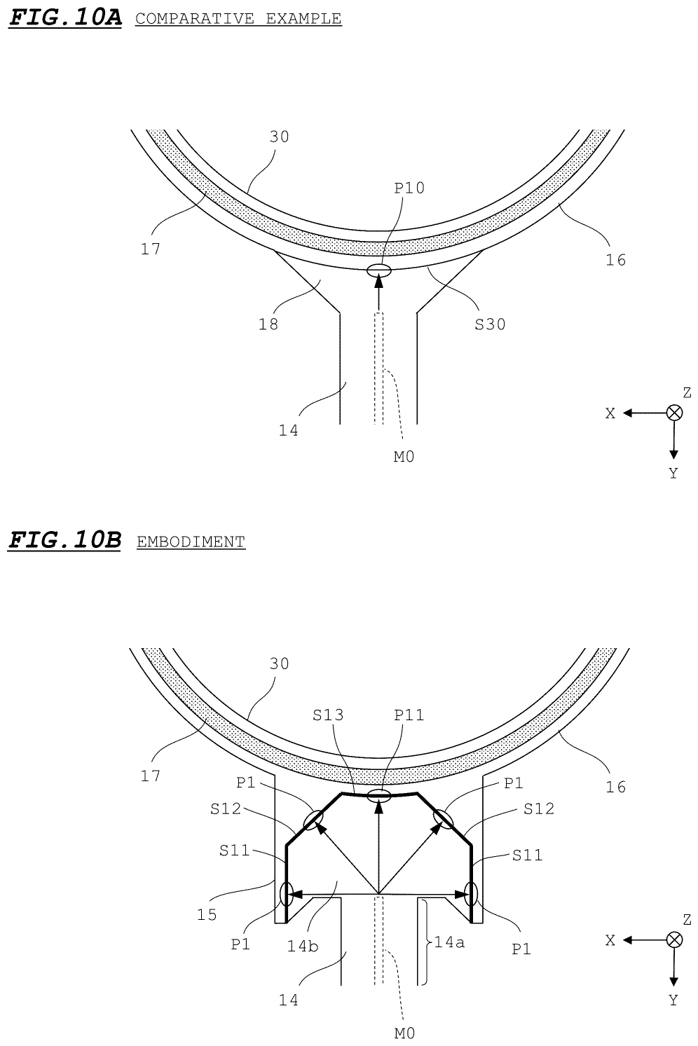

FIG. 10A is a plan view schematically showing propagation of stress according to the comparative example, and FIG. 10B is a plan view schematically showing propagation of stress according to the embodiment.

As shown in FIG. 10A, in the comparative example, stress is concentrated in a region MO at the center of the torsion part 14, through which the rotation axis R0 passes, during rotation of the torsion part 14. In the comparative example, since only the arc-shaped joint surface S30 which slightly bulges in the Y-axis direction exists, the stress in the region MO propagates to the position P10 in the vicinity of the center in the X-axis direction of the joint surface S30. Therefore, in the oxide film L3, high stress is localized at the position P0 close in the Z-axis direction to the position P10 at the center of the joint surface S30 as in the above verification result.

In contrast, in the embodiment, as shown in FIG. 10B, in addition to the joint surface S13, the pair of joint surfaces S11 which are symmetrical about and parallel to the rotation axis R0 and the pair of joint surfaces S12 which are symmetrical about the rotation axis R0 and inclined at a predetermined angle are located. That is, the pair of joint surfaces S11, the pair of joint surfaces S12, and the joint surface S13 are located so as to surround an end portion on the Y-axis negative side of the region MO. Therefore, the stress localized in the region MO is dispersed to the pair of joint surfaces S11 and the pair of joint surfaces S12 as well as the joint surface S13.

Accordingly, the stress generated at each of the positions P11 in the vicinities of the centers of the pair of joint surfaces S11, the pair of joint surfaces S12, and the joint surface S13 is alleviated as compared to the stress generated at the position P10 in the comparative example. Therefore, in the oxide film L3, as in the above verification result, stress is dispersed to the positions P1 at the joint surfaces S11, S12, and S13 close to the position P11 in the Z-axis direction, and this stress is alleviated as compared to the stress generated at the position P0 in the comparative example.

In the comparative example, since the stress generated during rotation of the movable part 30 is concentrated at one point on the joint surface S30 as described above, the bending distribution of the frame part 16 becomes steep as shown in FIG. 8A, so that the bending amount of the movable part 30 is increased. In contrast, in the embodiment, since the stress generated during rotation of the movable part 30 is dispersed to the pair of joint surfaces S11, the pair of joint surfaces S12, and the joint surface S13, the bending distribution of the frame part 16 is more gradual than in the comparative example as shown in FIG. 8B, so that the bending amount of the movable part 30 is reduced. Accordingly, in the configuration of the embodiment, the deformation of the reflection surface 40 during rotation of the movable part 30 can be effectively suppressed, so that the spread of a scanning beam can be suppressed.

In the configuration of the embodiment, as shown in FIG. 10B, the torsion part 14 is configured to include a shaft portion 14a extending along the rotation axis R0 and a wide portion 14b formed at an end portion on the frame part 16 side of the shaft portion 14a. In a plan view, the wide portion 14b is wider than the shaft portion 14a and is connected to the connection part 15 via the pair of joint surfaces S11, the pair of joint surfaces S12, and the joint surface S13. The other end of the shaft portion 14a is connected to the drive part 11.

Here, in the case where the wide portion 14b has springiness due to a face spring, the springiness can contribute to making the bending distribution of the frame part 16 gradual during rotation of the shaft portion 14a. In this case, in the configuration of the embodiment, in addition to the dispersion of stress to the joint surfaces S11 to S13, the bending of the frame part 16 can be effectively suppressed by the springiness of the wide portion 14b.

A region MO where stress becomes maximum occurs in the vicinity of the central axis of the shaft portion 14a, and this stress is dispersed to the pair of joint surfaces S11, the pair of joint surfaces S12, and the joint surface S13 via the wide portion 14b. The pair of joint surfaces S11, the pair of joint surfaces S12, and the joint surface S13 are set so as to surround the end point on the wide portion 14b side of the central axis of the shaft portion 14a. Accordingly, it is easier to disperse stress to these joint surfaces S11 to S13, so that it is easier to make the bending distribution of the frame part 16 gradual.

### Effects of Embodiment

According to the above embodiment, the following effects are achieved.

As described with reference to FIG. 9B and FIG. 10B, the stress generated during rotation of the movable part 30 is more likely to spread to be dispersed to the pair of joint surfaces S11 and the pair of joint surfaces S12. Accordingly, as shown in FIG. 8B, the bending of the frame parts 16 and 26 during rotation of the movable part 30 becomes gradual, so that the bending of the movable part 30 connected to the frame parts 16 and 26 is suppressed. Therefore, even when the movable part 30 is driven at a high frequency and a high deflection angle, the bending of the movable part 30 and the reflection surface 40 can be effectively suppressed.

As shown in FIG. 6, the connection parts 15 and 25 have larger thicknesses than the torsion part 14, and have thickness ranges (non-joint ranges 15b and 25b) not connected to the torsion part 14, and the wall surfaces S21 and S22 connected to the joint surfaces S11 and S12 are formed in each of the thickness ranges (non-joint ranges 15b and 25b). In this configuration, by forming the pair of wall surfaces S21 and the pair of wall surfaces S22 in each of the non-joint ranges 15b and 25b, the pair of joint surfaces S11 and the pair of joint surfaces S12 connected to the pair of wall surfaces S21 and the pair of wall surfaces S22 in the Z-axis positive direction can be formed in each of the joint ranges 15a and 25a.

As shown in FIG. 6, the pair of joint surfaces S11 are parallel to the rotation axis R0, and the pair of joint surfaces S12 are non-parallel to the rotation axis R0. Accordingly, the stress generated during repetitive rotation of the movable part 30 can be dispersed to the pair of joint surfaces S11 and to the pair of joint surfaces S12. Therefore, the bending of the frame parts 16 and 26 during rotational movement can be effectively suppressed, so that the bending of the movable part 30 and the reflection surface 40 can be effectively suppressed.

As shown in FIG. 6, the connection parts 15 and 25 have the pair of joint surfaces S11 (first pair of joint surfaces) and the pair of joint surfaces S12 (second pair of joint surfaces) which are positioned closer to the frame parts 16 and 26 than the pair of joint surfaces S11 are and whose angles with the rotation axis R0 are larger than those of the pair of joint surfaces S11. Accordingly, the pair of joint surfaces S11 and the pair of joint surfaces S12 are located so as to surround the end portion on the Y-axis negative side of the torsion part 14, so that the stress generated during repetitive rotation is more likely to be dispersed to the pair of joint surfaces S11 and the pair of joint surfaces S12. Therefore, the bending of the frame parts 16 and 26 during rotational movement can be effectively suppressed, so that the bending of the movable part 30 and the reflection surface 40 can be effectively suppressed.

As shown in FIG. 1 and FIG. 2, the first drive unit 10 which includes the frame part 16, the torsion part 14, the connection part 15, the drive part 11, and the fixation part 12, and the second drive unit 20 which includes the frame part 26, the torsion part 24, the connection part 25, the drive part 21, and the fixation part 22, are placed in orientations opposite to each other with the movable part 30 located therebetween, and the frame parts 16 and 26 of the respective drive units are connected to the movable part 30. Thus, by supporting and driving the movable part 30 with the respective drive units, the movable part 30 can be driven stably with a larger torque.

As shown in FIG. 1, the drive parts 11 and 21 are tuning fork-type drive parts, and have the piezoelectric thin films 112a and 212a as drive sources. Accordingly, the movable part 30 can be smoothly and repeatedly rotated about the rotation axis R0.

### MODIFICATIONS

In the above embodiment, the pair of joint surfaces S11 and the pair of joint surfaces S12 are formed in each of the connection parts 15 and 25, but either pair of joint surfaces may be omitted.

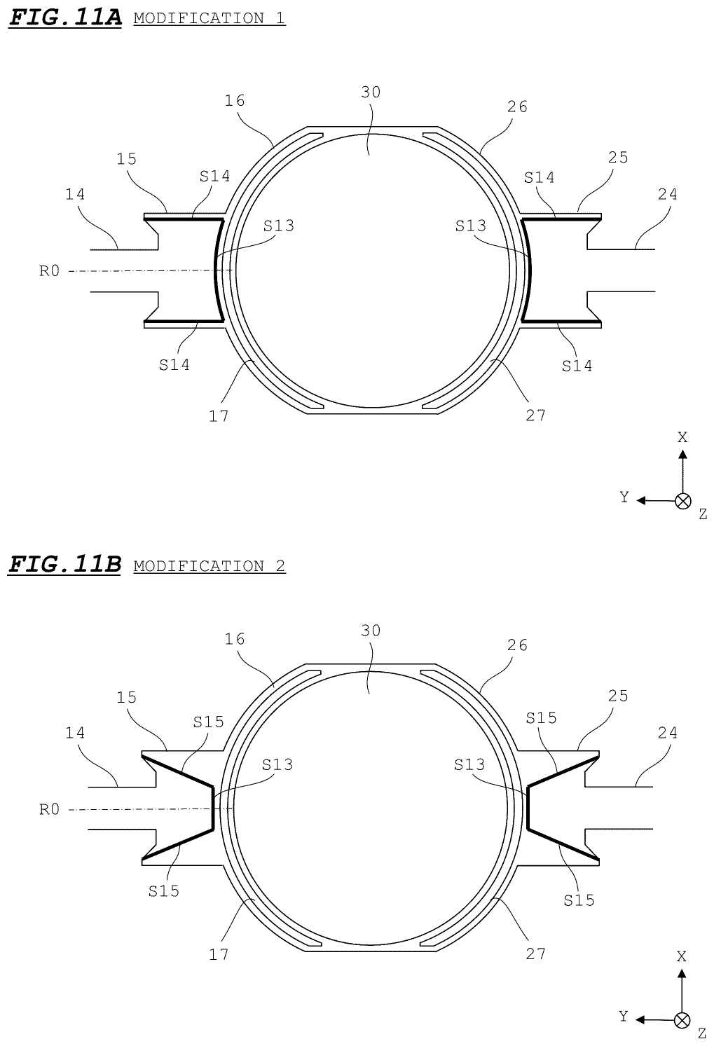

For example, as shown in FIG. 11A, a pair of joint surfaces S14 parallel to the rotation axis R0 and a joint surface S13 intersecting the rotation axis R0 may be formed in each of the connection parts 15 and 25. Alternatively, as shown in FIG. 11B, a pair of joint surfaces S15 inclined with respect to the rotation axis R0 and a joint surface S13 intersecting the rotation axis R0 may be formed in each of the connection parts 15 and 25.

Even with these configurations, the stress generated during repetitive rotation of the movable part 30 can be dispersed to the pair of joint surfaces S14 and the pair of joint surfaces S15. Therefore, the bending of the frame parts 16 and 26 during rotational movement can be effectively suppressed, so that the bending of the movable part 30 and the reflection surface 40 can be effectively suppressed.

In the above embodiment, the pair of joint surfaces S11 and the pair of joint surfaces S12 are flat surfaces, but these joint surfaces may be curved surfaces.

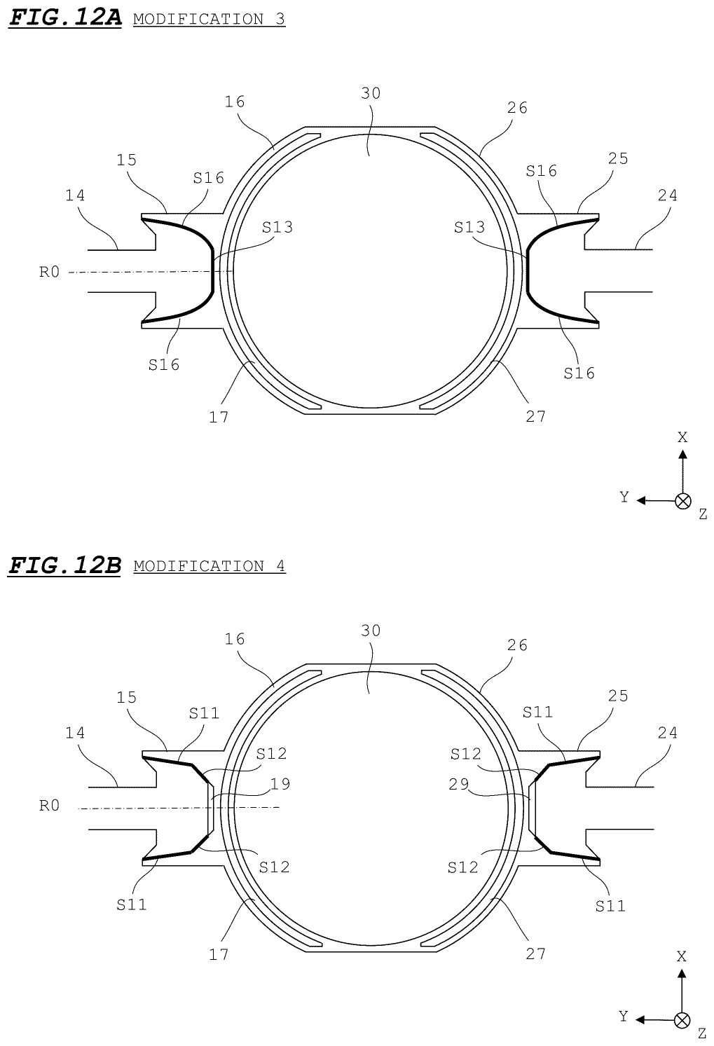

For example, as shown FIG. 12A, a pair of joint surfaces S16 facing each other across the rotation axis R0 and a joint surface S13 intersecting the rotation axis R0 may be formed in each of the connection parts 15 and 25. Here, the shapes of the pair of joint surfaces S16 are each set to be recessed in a direction away from the rotation axis R0, and the generatrices thereof are set to have a curved surface shape parallel to the Z axis. Such a shape of each joint surface S16 can be set by adjusting the shape of a wall surface connected to the joint surface S16 in each of the non-joint ranges 15b and 25b of the connection parts 15 and 25 to the same shape as that of the joint surface S16 in a plan view as in the above embodiment.

Even with this configuration, the stress generated during repetitive rotation of the movable part 30 can be dispersed to the pair of joint surfaces S16. Therefore, the bending of the frame parts 16 and 26 during rotational movement can be effectively suppressed, so that the bending of the movable part 30 and the reflection surface 40 can be effectively suppressed.

In the above embodiment, the pair of joint surfaces S11 are parallel to the rotation axis R0, but the pair of joint surfaces S11 may be non-parallel to the rotation axis R0. For example, as shown in FIG. 12B, the pair of joint surfaces S11 may be inclined such that the angles between the pair of joint surfaces S11 and the rotation axis R0 are acute angles.

As shown in FIG. 12B, gaps 19 and 29 may be formed between end portions on the movable part 30 side of the pairs of joint surfaces S12, and the torsion parts 14 and 24 and the connection parts 15 and 25 may be separated from each other at the gaps 19 and 29.

Even with this configuration, the stress generated during repetitive rotation of the movable part 30 can be dispersed to the pair of joint surfaces S11 and the pair of joint surfaces S12. Therefore, the bending of the frame parts 16 and 26 during rotational movement can be effectively suppressed, so that the bending of the movable part 30 and the reflection surface 40 can be effectively suppressed.

In the modifications shown in FIG. 11A to FIG. 12A, a gap penetrating in the Z-axis direction may also be provided in the range of each joint surface S13.

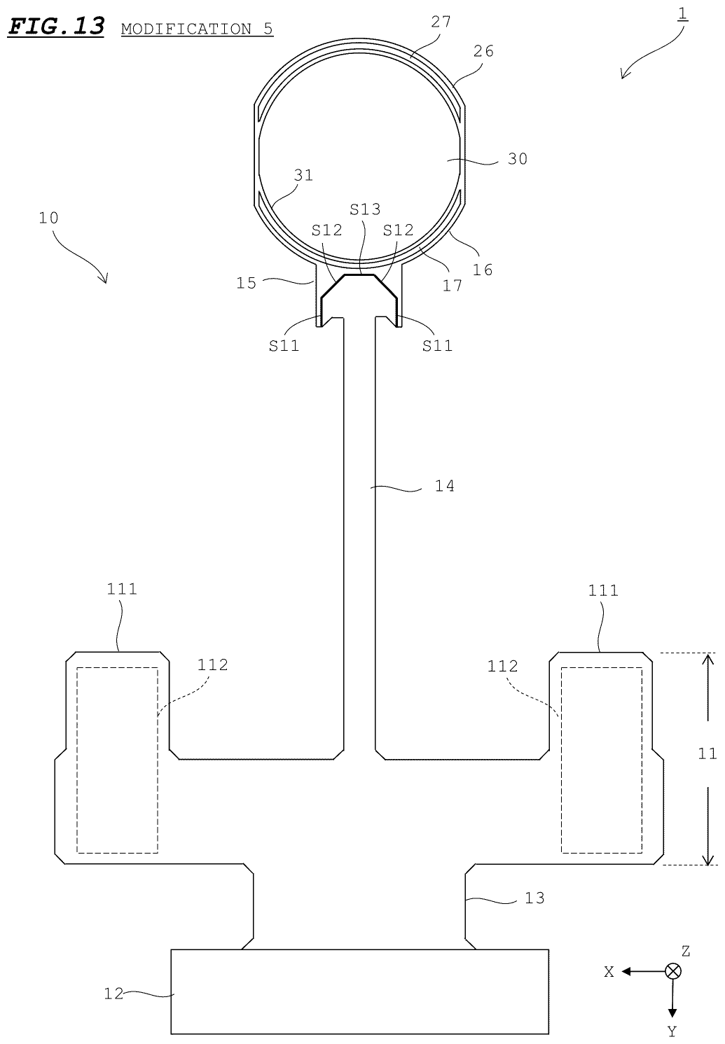

In the above embodiment, the first drive unit 10 and the second drive unit 20 are placed with the movable part 30 located therebetween in the Y-axis direction, but, for example, as shown in FIG. 13, the second drive unit 20 may be omitted, and the movable part 30 may be rotated by only the first drive unit 10. In this configuration as well, the stress generated in the torsion part 14 during repetitive rotation of the movable part 30 is dispersed to the pair of joint surfaces S11, the pair of joint surfaces S12, and the joint surface S13, so that the bending of the frame part 16 is suppressed. Therefore, the bending of the movable part 30 and the reflection surface 40 during rotational movement can be effectively suppressed.

In the above embodiment and modifications, the shape of the movable part 30 is circular, but the shape of the movable part 30 may be another shape such as a square. The shape of the optical reflective device 1 in a plan view and the dimensions of each part of the optical reflective device 1 can also be changed as appropriate. The simulation conditions shown in the verification and the optical scanning angle of the reflection surface 40 and the frequency of repetitive rotation are also examples, and the values of various parameters are not limited to these values.

In addition to the above, various modifications can be made as appropriate to the embodiment of the present invention, without departing from the scope of the technological idea defined by the claims.

What is claimed is:

1. An optical reflective device comprising:
a movable part configured to be rotated about a rotation axis;
a reflection surface located on the movable part;
a frame part placed on an outer side of the movable part with a predetermined gap in a plan view and connected to the movable part at two positions symmetrical about the rotation axis;
a beam-like torsion part extending along the rotation axis;
a connection part connecting one end of the torsion part to the frame part;
a drive part connected to another end of the torsion part and configured to rotate the torsion part about the rotation axis; and
a fixation part supporting the drive part, wherein
the connection part has higher rigidity than the torsion part,
at least one pair of joint surfaces are formed at a boundary between the torsion part and the connection part, and
the one pair of joint surfaces are symmetrical about the rotation axis and each have an acute angle on the torsion part side with the rotation axis.

2. The optical reflective device according to claim 1, wherein
the connection part has a larger thickness than the torsion part and has a thickness range not connected to the torsion part, and
wall surfaces connected to the joint surfaces are formed in the thickness range.

3. The optical reflective device according to claim 1, wherein the one pair of joint surfaces are parallel to the rotation axis.

4. The optical reflective device according to claim 1, wherein the one pair of joint surfaces are non-parallel to the rotation axis.

5. The optical reflective device according to claim 1, wherein the at least one pair of joint surfaces include
a first pair of joint surfaces, and
a second pair of joint surfaces which are positioned closer to the frame part than the first pair of joint surfaces are and whose angles with the rotation axis are larger than those of the first pair of joint surfaces.

6. The optical reflective device according to claim 5, wherein the first pair of joint surfaces are parallel to the rotation axis.

7. The optical reflective device according to claim 1, wherein
two drive units each including the frame part, the torsion part, the connection part, the drive part, and the fixation part are placed in orientations opposite to each other with the movable part located therebetween, and
the frame parts of the respective drive units are connected to the movable part.

8. The optical reflective device according to claim 1, wherein the drive part has a piezoelectric thin film as a drive source.
